(19) United States
(12) Patent Application Publication
(10) Pub. No.: US 2006/0022244 A1
(43) Pub. Date: Feb. 2, 2006

(54) High Density Non-volatile Memory Devices

(75) Inventor: Jeng-Jye Shau, Palo Alto, CA (US)

Correspondence Address: JENG-JYE SHAU, 991 AMARILLO AVE., PALO ALTO, CA, 94303, US

(73) Assignee: Jeng Jye Shau, Palo Alto, CA (US)

(21) Appl. No.: 11/162,762

(22) Filed: Oct. 21, 2005

Related U.S. Application Data
(63) Continuation-in-part of application No. 10/796,318, filed on Mar. 9, 2004.

(51) Int. Cl. H01L 29/94

(52) U.S. Cl. 257/296

(57) ABSTRACT

The present invention provides methods to arrange non-volatile memory transistor array by rotating the word line and bit line directions 90 degrees relative to that of prior art NOR FLASH devices. These methods effectively reduce the areas of non-volatile memory devices. Additional changes in control mechanism are required to support the operations of such non-volatile memory devices.

This application is a continue-in-part application of another co-pending patent application with Ser. No. 10,796,318, titled “Capacitor Coupling Circuits”, filed Mar. 9, 2004.

### DESCRIPTION

### BACKGROUND OF THE INVENTION

The present invention relates to integrated circuit (IC) devices, and more particularly to high density non-volatile memory devices.

Most part of previous co-pending application (Ser. No. 10,796,318) disclosed applications of capacitor coupling circuits. In addition, FIGS. 9(e-g) of previous application disclosed current mode operations of floating gate transistors. The floating gate transistors were arranged in a configuration that rotated the word line and bit line directions by 90 degrees relative to the word line and bit line directions of prior art NOR FLASH devices. Adding FIGS. 11(a-f) and FIGS. 12(a-f), this application provides more examples for the current mode floating gate devices disclosed in the co-pending application.

The present invention utilizes the voltage controlled capacitor (VCC) of metal-oxide-semiconductor (MOS) devices to support circuit operations. To facilitate better understanding of the present invention, the voltage dependence of MOS capacitor is first discussed. FIG. 1(a) illustrates the structure of a typical MOS capacitor, where a conductor layer (M) is separated from a semiconductor (S) layer by an insulator (0) thin film layer. The conductor layer (M) can be a metal layer or another semiconductor layer. Typical examples of the insulator layer (O) are silicon dioxide (oxide), silicon nitride (nitride), combination of oxide-nitride (ON) layers, or oxide-nitride-oxide (ONO) layers. The most popular semiconductor used in IC industry is certainly silicon. Dependent on the voltage bias conditions, there maybe a depletion region (D) in the semiconductor layer (S). The equivalent capacitance (Ct) of the MOS device in FIG. 1(a) equals the equivalent capacitor of insulator (Co) in series with the capacitor (Cs) of the semiconductor depletion layer as shown in the simplified schematic diagram in FIG. 1(b), and we have
Ct=(Cs*Co)/(Cs+Co) (1),
Co=eₒA/Xo (2),
Vs=1/eₛIₙₜq(x)×dx (3),
Qs=AIₙₜq(x)dx (4),
Cs=Qs/Vs (5),

Where A is area of the device, eₒ is the equivalent dielectric constant of the insulator layer (O), es is the dielectric constant of the semiconductor (S), Vs is the voltage drop in semiconductor depletion region (D), Iₙₜ is a symbol means integration, x is the location measured from the interface between oxide and semiconductor, q(x) is the electrical charge in depletion region at location x, and Qs is the total electrical charge in semiconductor depletion region. The space charge q(x) is a function of doping profile created during semiconductor manufacture procedures. For the simplified case when the doping profile is a constant with value Ns, we have Vs=(Ns*Xd²/2eₛ), Qs=Ns A Xd, and Cs=2eₛA/Xd, where Xd is the thickness of the semiconductor depletion layer (D). FIG. 1(d) shows the value of capacitor seen from the semiconductor substrate (Ct) as a function of bias voltage (v). When the MOS device bias voltage (v) is lower than accumulation threshold voltage (Vta), the oxide-semiconductor interface is in the accumulation condition, and there is no deletion region in the semiconductor so that we have Ct=Co. When the bias voltage is between Vta and the inversion threshold voltage (Vti), the MOS device is biased into depletion condition, Ct decreases with increasing Xd as shown in FIG. 1(b). When the MOS device is biased into inversion condition (v>Vti), an inversion layer is formed at the oxide-semiconductor interface so that the depletion region no longer change with bias voltage. Under inversion conditions, we have Ct=Ci=Cdmin*Co/(Cdmin+Co), where Ci is the capacitance of the device at inversion condition, and Cdmin is the capacitance of the depletion region under inversion condition. At inversion condition, Ct reaches a minimum value as shown in FIG. 1(b). The above conditions assumed that the semiconductor substrate is p-type. For n-type substrate, the polarities of voltages are inverted. Formation of inversion layer requires supply of minority charge carrier, which takes time to reach stead state condition. Therefore, Ct at inversion condition maybe a function of frequency, transient time, and availability of minority carriers. The effective capacitance at inversion condition also maybe different when it is measured from the conductor (M) versus measured from the semiconductor node (S) because of the inversion layer. Further details of the above device properties can be found in semiconductor text books such as “Semiconductor Devices” authored by S. M. Sze. The key factors utilized by the present invention is that the effective capacitance of an MOS device is much higher at accumulation condition than the capacitance at depletion or inversion conditions as shown in FIG. 1(b). In the ways the present invention uses MOS capacitor, it behaves like a capacitor and a diode connected in series. That is why the symbol in FIG. 1(c) is used as the symbol for an MOS capacitor with p-type semiconductor substrate, and the symbol in FIG. 1(d) is used to represent an MOS capacitor with n-type semiconductor substrate.

FIG. 2(a) shows the structure for a floating gate capacitor. A conductor layer (G) is separated from a floating conductor layer (FG) by a floating gate insulator layer (O_{f}). This floating gate (FG) is separated from the semiconductor substrate (S) by the gate insulator layer (O_{g}). The floating gate (FG) is surrounded by insulators so that it can trap and store electrical charges. The trapped charges stored in the floating gate are called floating gate charge (Qf). Dependent on the bias voltage and Qf, there maybe a depletion region (D) in the semiconductor layer. The equivalent capacitance of the floating gate device (Ctf) is the series capacitance of the floating gate insulator (Cf), the capacitance of the gate insulator (Cg) and the capacitance of the semiconductor depletion area (Cd) as shown in the schematic diagram in FIG. 2(b). We have
Ctf=(Cf*Cg*Cd)/(Cf*Cg+Cf*Cd+Cg*Cd) (6),
Cf=e_{f}A/Xf (7),
Cg=e_{g}A/Xg (8),
Vd=1/eₛIₙₜq(x)×dx (9),
Qd=AIₙₜq(x)dx (10),
Cd=Qd/Vd (11),

Where A is the area of the device, e_{f} is the equivalent dielectric constant of the floating gate insulator layer (O_{f}), e_{g} is the dielectric constant of the gate insulator layer (O_{g}), Vd is the voltage drop in semiconductor depletion region (D), x is the location measured from the interface between oxide and semiconductor, q(x) is the electrical charge in depletion region at location x, and Qd is the total electrical charge in semiconductor depletion region that is a function of doping profile created during semiconductor manufacture procedures. If there is no charge stored in the floating gate (FG), i.e. when Qf=0, the device in FIG. 2(a) behaves in the same ways as a MOS device in FIG. 1(a) with an equivalent gate capacitance Ce=[(Cf*Cg)/(Cf+Cg)]. Its capacitance-voltage (C-V) relationship is shown as the first line in FIG. 2(b). If there are electrical charges (Qf) trapped in the floating gate (FG), the C-V relationship would be shifted by a voltage Vf=(Qf/Cg) as the second line in FIG. 2(b), where Cif is the capacitance for the floating gate device under inversion condition. The trapped charge Qf also changes the accumulation threshold voltages from Vta to Vta′, and changes the inversion threshold voltage from Vti to Vti′ by the same amplitude Vf, as shown in FIG. 2(b). The charge stored in the floating gate (Qf) can be changed by similar methods used in prior art erasable programmable read only memory (EPROM) devices. For example, electrons can be pulled into the floating gate by applying a positive high voltage between gate and substrate. Another common method is to utilize hot electron effects. Electrons can be pulled out of the floating gate by reversing the voltage polarity. In the ways the present invention uses floating gate capacitor, it behaves like two capacitors and a diode connected in series. That is why the symbol in FIG. 2(c) is used as the symbol for a floating gate capacitor with p-type semiconductor substrate, and the symbol in FIG. 2(d) is used to represent a floating gate capacitor with n-type semiconductor substrate.

The present invention was originally developed to reduce the area of programmable logic array (PLA) devices by reducing the size of the minterms in PLA. Prior art PLA's use transistors to support desired operations while the present invention uses capacitors to replace transistors to reduce cost and power of PLA. This invention also makes it practical to make three dimensional devices. After further details of the present invention were developed, it was realized that similar structures of the present invention can support other applications including but not limited to field programmable logic (FPG) devices, different types of logic circuits, comparators, parity calculation, or nonvolatile memory devices. The cost and power consumption for all those devices will be reduced dramatically by the present invention.

### SUMMARY OF THE INVENTION

The primary objective of this invention is, therefore, to reduce the area of non-volatile memory devices. Another objective of this invention is to simplify the manufacture procedures for non-volatile memory devices. These and other objectives are accomplished by rearranging the word line and bit line directions relative to that of prior art NOR FLASH devices.

While the novel features of the invention are set forth with particularly in the appended claims, the invention, both as to organization and content, will be better understood and appreciated, along with other objects and features thereof, from the following detailed description taken in conjunction with the drawing.

### BRIEF DESCRIPTION OF THE DRAWINGS

FIG. 1(a) shows the structure of an MOS capacitor;

FIG. 1(b) shows the capacitance-voltage (C-V) relationship of the device in FIG. 1(a);

FIG. 1(c) is the schematic symbol used to represent a MOS capacitor with p-type substrate;

FIG. 1(d) is the schematic symbol used to represent a MOS capacitor with n-type substrate;

FIG. 2(a) shows the structure of a floating gate capacitor;

FIG. 2(b) shows the C-V relationship of the device in FIG. 2(a);

FIG. 2(c) is the schematic symbol used to represent a floating gate capacitor with p-type substrate;

FIG. 2(d) is the schematic symbol used to represent a floating gate capacitor with n-type substrate;

FIG. 3(a) is a schematic diagram for a minterm of a prior art PLA circuit;

FIG. 3(b) shows operation waveforms of a prior art PLA circuit;

FIG. 4(a) is the schematic diagram for a capacitor PLA minterm of the present invention that provides the same logic function as the circuit shown in FIG. 3(a);

FIG. 4(b) shows the physical structure for the capacitor coupling circuit in FIG. 4(a);

FIG. 4(c) shows structures of a 3D capacitor coupling circuits of the present invention;

FIG. 4(d) shows operation waveforms of the circuit in FIG. 4(a);

FIG. 4(e) illustrates an application of the present invention as optical sensors;

FIG. 5(a) is the schematic diagram for a programmable PLA minterm of the present invention that can provide the same logic function as the circuit shown in FIG. 3(a);

FIG. 5(b) shows the physical structure for the coupling circuit in FIG. 5(a);

FIG. 5(c) shows structures of a 3D programmable coupling circuit;

FIG. 5(d) shows operation waveforms of the circuit in FIG. 5(a);

FIG. 5(e) shows the physical structure for a coupling circuit of the present invention equipped with NAND operation capability;

FIG. 5(f) shows structures of a 3D structure for the device in FIG. 5(e);

FIGS. 6(a-g) illustrate the manufacture procedure for floating gate coupling circuits (FGCC) of the present invention;

FIGS. 7(a-f) show an alternative manufacture procedure for FGCC of the present invention;

FIGS. 8(a-f) show another manufacture procedure for FGCC of the present invention;

FIG. 9(a) is a schematic diagram for an array of floating gate capacitors of the present invention performing as a storage device;

FIGS. 9(b-d) illustrate the operation waveforms for the device in FIG. 9(a);

FIG. 9(e) is a schematic diagram for an array of floating gate transistors of the present invention;

FIG. 9(f) shows the structural top view for the device in FIG. 9(e);

FIG. 9(g) shows the top view of prior art NOR FLASH device;

FIG. 10 is a block diagram for yield enhancement methods of the present invention;

FIGS. 11(a-f) illustrate one example of the manufacture procedures for floating gate devices of the present invention; and

FIGS. 12(a-f) illustrate another example of the manufacture procedures for floating gate devices of the present invention.

### DETAILED DESCRIPTION OF THE INVENTION

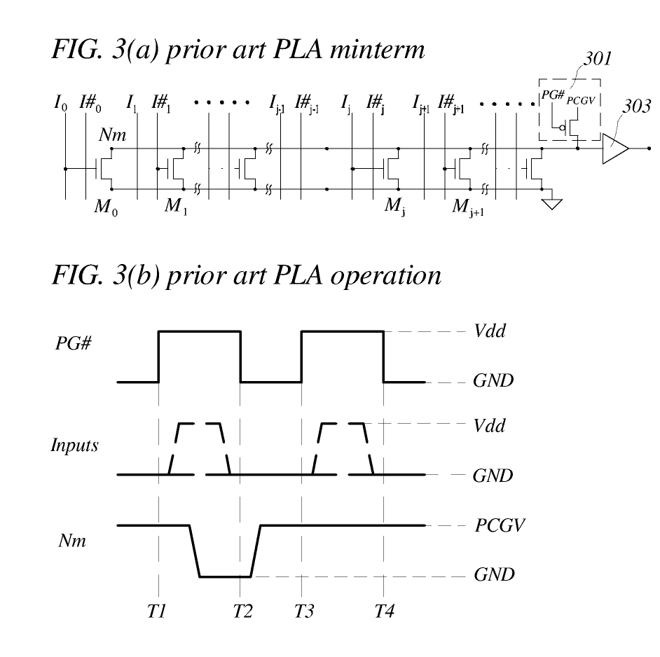

Typical structures of prior art PLA minterm are first discussed to facilitate understanding of the present invention. FIG. 3(a) is the schematic diagram for a prior art PLA minterm. A plurality of PLA input signals (I₀, I₁, . . . Iⱼ₋₁, Iⱼ, Iⱼ₊₁, . . . ) and their corresponding complemented signals (I#₀, I#₁, . . . I#ⱼ₋₁, I#ⱼ, I#ⱼ₊₁, . . . ) are selectively connected to the gates of a plurality of pull-down transistors (M₀, M₁, . . . , Mⱼ, Mⱼ₊₁, . . . ). The sources of those transistors are all connected to ground, while their drains are all connected to a minterm output line (Nm) that is connected to a pre-charge circuit (301) and a sensing circuit (303). Detailed designs for the pre-charge circuit and the sensing circuit are well-known to the art of IC circuit design. FIG. 3(a) shows a simple example of a pre-charge circuit that comprises one p-channel transistor. The source of the transistor is connected to pre-charge voltage (PCGV), its gate is connected to pre-charge control signal PG#, and its drain is connected to Nm. Details of the sensing circuit (303) are not shown. The gates of those transistors (M₀, M₁, . . . , Mⱼ, Mⱼ₊₁, . . . ) are connected to one of the inputs or complemented inputs. Sometimes a pair of input signal (Iⱼ₋₁ and I#ⱼ₋₁ in this example) are not connected to any transistor; that means this unconnected input pair is not related to the logic operation of this particular minterm. FIG. 3(b) is a simplified illustration for operation waveforms of the PLA mintermin in FIG. 3(a). Before time T1, the PLA is at idle state, and the pre-charge control signal PG# is low so that the minterm output signal Nm is charged to voltage PCGV. When the prior art PLA is at idle state, all the transistors in the minterm are deactivated by setting all input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) to low. To start a logic calculation at time T1, the pre-charge circuit (301) is turned off by pulling PG# high, and the input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) are set to their corresponding logic states, and the sensing circuit (303) detects the desired results of the connected input signals. For example, a logic state ‘1’ on input 0 is represented by maintaining I#₀ at ground voltage (Vss) while pulling I₀ up to power supply voltage (Vdd); a logic state ‘0’ on input 0 is represented by maintaining I₀ at Vss while pulling I#₀ up to Vdd. At time T2, all the inputs return to low while PG# is also pulled low, then the circuit returns to idle state. Another cycle is started at time T3 for another set of input signals, and returns to idle state at T4. For the example in FIG. 3(a), the logic state on the Nm line will be the NOR of connected input signals (I₀, . . . Iⱼ₊₁, . . . , I#₁, . . . I#ⱼ, . . . ) during the evaluation cycles. In other words, if any one of the connected input signals (I₀, . . . Iⱼ₊₁, . . . , I#₁, . . . I#ⱼ, . . . ) is high, the output line Nm will be low as shown in the first cycle in the example in FIG. 3(b); when all the connected input signals are low, the output line Nm remains high as the second cycle in FIG. 3(b). Using a large number of minterms with desired combinations of connections to the input signals, a prior art PLA can execute large fan-in logic calculations at high speed with excellent flexibility.

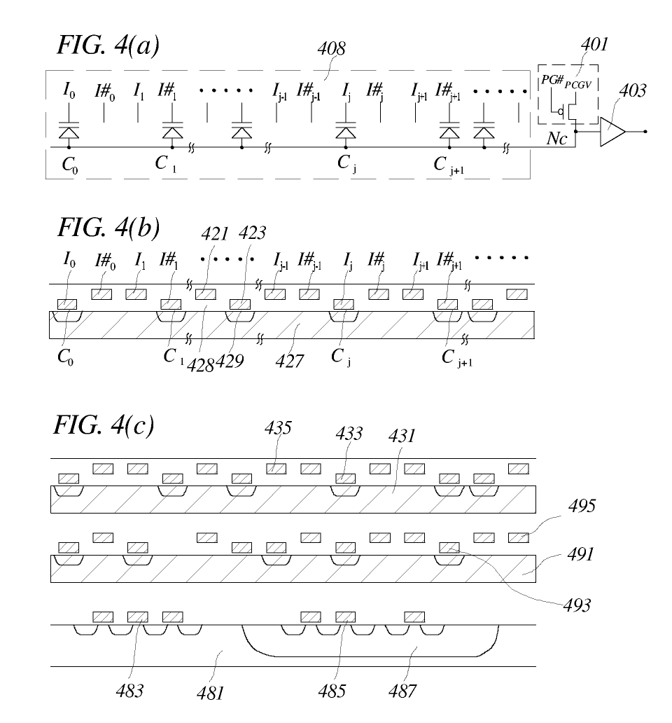

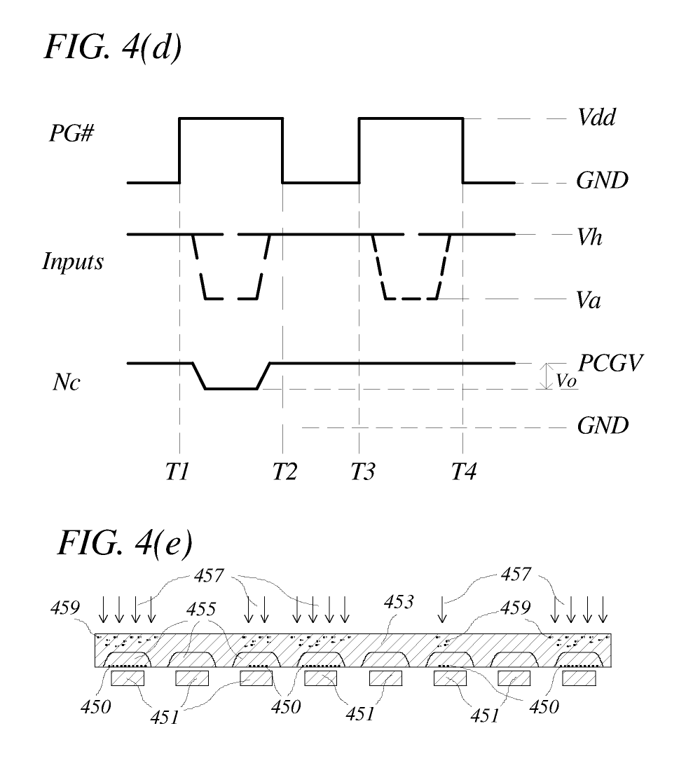

The above prior art circuits use MOS devices as three terminal transistors working as current sinks to support logic operations. The present invention uses MOS devices as two terminal voltage controlled capacitor (VCC), and uses voltage coupling effects to support logic operations. FIG. 4(a) shows the schematic diagram for a PLA minterm of the present invention that has the same logic function as the prior art minterm in FIG. 3(a). The PLA input signals (I₀, I₁, . . . Iⱼ₋₁, Iⱼ, Iⱼ₊₁, . . . ) and their complemented input signals (I#₀, I#₁, . . . I#ⱼ₋₁, I#ⱼ, I#ⱼ₊₁, . . . ) are selectively connected to the negative terminals of MOS capacitors (C₀, C₁, . . . , Cⱼ, Cⱼ₊₁, . . . ). For this example, the particular input connections in FIG. 4(a) provides identical logic function as the prior art example in FIG. 3(a). The positive terminals of those capacitors are all connected to an output line (Nc) that is connected to a pre-charge circuit (401) and a sensing circuit (403). Detailed structures for the pre-charge circuit and the sensing circuit are well-known to the art of IC circuit design. The example in FIG. 4(a) uses the same pre-charge circuit (401) as the example (301) in FIG. 3(a). Details of the sensing circuit (403) are not shown because they are well known to the art of IC design. FIG. 4(d) illustrates the operation waveforms for the PLA mintermin in FIG. 4(a). Before time T1, the PLA is at idle state, and the pre-charge control signal PG# is low so that the output signal Nc is charged to voltage PCGV. At idle state, all the input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) are set at a voltage called idle state voltage (Vh) as shown in FIG. 4(d). At idle state voltage Vh, the MOS capacitors are biased into depletion conditions or inversion conditions, so that their coupling capacitances to Nc are small. To start a logic calculation at time T1, the pre-charge circuit (401) is turned off by pulling PG# high, and the input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) are set to their corresponding logic states. For example, a logic state ‘1’ on input 0 is represented by maintaining I#₀ at Vh while pulling I₀ down to activation voltage (Va); a logic state ‘0’ on input 0 is represented by maintaining I₀ at Vh while pulling I#₀ down to Va. The activation voltage Va is a voltage below accumulation threshold voltage (Vta) of the MOS capacitors. At time T2, all the inputs return to Vh while PG# is also pulled low, then the circuit returns to idle state. Another cycle is started at time T3 for another set of input signals, and return to idle state at T4. Under these conditions, if any one of the connected input signals (I₀, . . . Iⱼ₊₁, . . . , I#₁, . . . I#ⱼ, . . . ) is ‘1’, due to capacitor coupling effects, a voltage (Vo) would be coupled to the output line Nc as shown in the first cycle between T1 and T2 in FIG. 4(d). If none of the connected input signals (I₀, . . . Iⱼ₊₁, . . . , I#₁, . . . I#ⱼ, . . . ) is ‘1’, no voltage is coupled into the output line Nc as shown in the second cycle between T3 and T4 in FIG. 4(d). The amplitude of the coupling voltage (Vo) can be written as
Vo=(Vta−Va)Cin/Cp (12),

where Cin is the value of capacitance on all the connected inputs that are switched to voltage Va, and Cp is the total capacitance on the output line Nc. The sensing circuit (403) is designed to sense the coupling voltage Vo to provide desired output. Although we can use current art small signal sensing circuit to detect voltage changes as low as a few mini-volts, it is desirable to maximize the amplitude of the signal voltage Vo for reliable operations. The waveforms shown in FIG. 4(d) are simplified ideal waveform. There are noises on Nc for practical circuits. In order to maximize signal to noise ratio, we want to increase the (Cin/Cp) ratio as much as possible. Besides parasitic capacitance, the major contribution to Cp is the total capacitance of the MOS capacitors connected to inputs that are remaining at voltage Vh. That is why we select Vh at a voltage within depletion or inversion conditions to minimize idle state capacitor value, while select Va at a voltage within accumulation condition to maximize active state capacitor value.

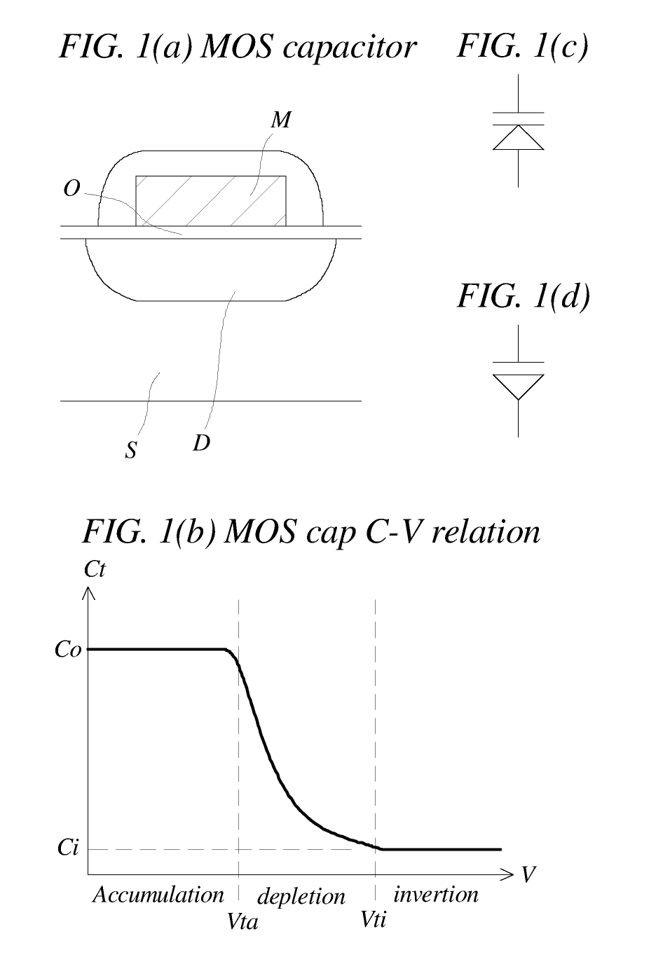

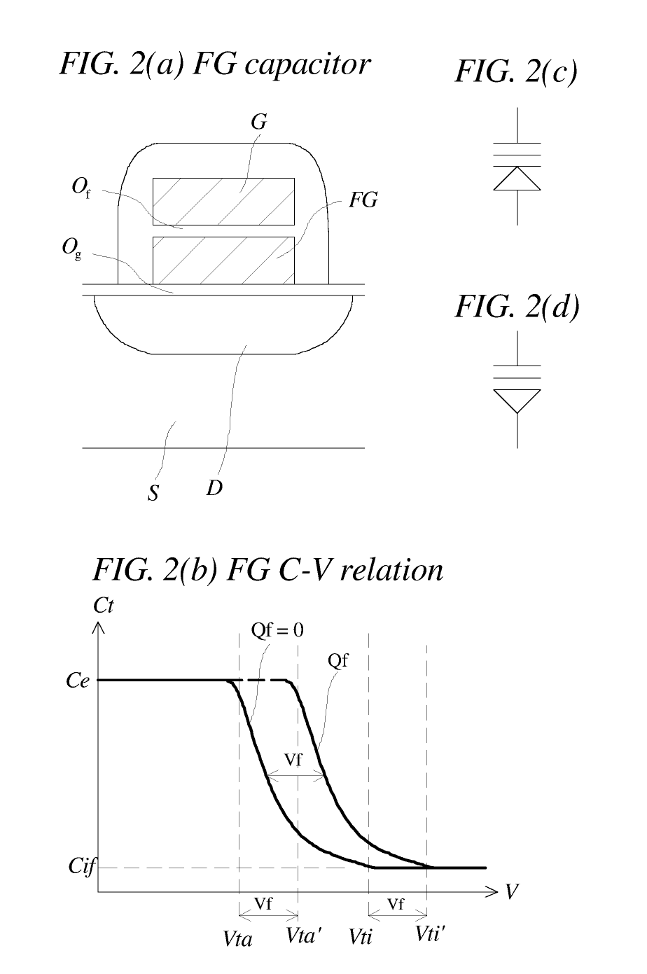

FIG. 4(b) is a cross-section diagram showing the physical structures of the input circuits (408) in FIG. 4(a). The input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) in FIG. 4(a) are conductor lines (421, 423) in FIG. 4(b). The output note Nc in FIG. 4(a) is an p-type semiconductor substrate (427) in FIG. 4(b). This substrate (427) can be a poly semiconductor layer or a diffusion area in single crystal substrate. If an input line (421) is separated from the substrate (427) by thick insulator layer (428), then that input line (421) does not have a connection to the substrate. If an input line (423) is separated from the substrate (427) by a thin insulator layer (429), then that input line is connected to the substrate through an MOS capacitor. In this way, the structure shown in FIG. 4(b) supports the same function as the input circuit (408) shown in FIG. 1(a).

The present invention uses capacitors to replace the function of transistors to achieve smaller area. Smaller signal to noise ratio is the major disadvantage for this invention; this disadvantage usually can be overcome with proper design on the sensing circuit. A major advantage for the coupling circuit of the present invention is that we do not need to use single crystal semiconductor as the substrate. Transistors must be built on high quality single crystal semiconductor substrate, while IC industry is fully capable of growing high quality insulator on lower quality semiconductor layers, such as poly silicon layers. It is therefore practical to build input circuits of the present invention on lower quality substrates. FIG. 4(c) shows the cross-section view of a three-dimensional (3D) device of the present invention using poly semiconductor substrates. In this example, there are two layers of poly semiconductor substrates (431, 491). Conductor lines (433, 435) are placed on top of one poly substrate (431) to form coupling circuits of the present invention similar to the structure shown in FIG. 4(b). Another set of conductor lines (493, 495) are placed on top of another poly substrate (491) to form similar coupling circuits of the present invention. On the single crystal semiconductor substrate (481) we still can have prior art transistors (483, 485) sharing the same area as coupling circuits of the present invention. Typical n-channel transistors (483) and p-channel transistors in n-well (487) are shown in the example in FIG. 4(c). Coupling circuits of the present invention also can be placed on the single crystal substrate (not shown in this figure). Such 3D device can achieve device density many times higher than prior art IC.

We uses an application on PLA minterm in the above examples, while similar circuits can support other applications such as logic gates, comparators, storage devices, etc. Specific applications should not limit the scope of the present invention. FIG. 4(e) shows an application of the present invention as optical sensor. In this example, MOS capacitors are formed between input lines (451) and p-type semiconductor substrate (453). These MOS capacitors are upside down comparing to those in FIG. 4(b). At idle states, the voltages on input lines (451) set all capacitors into depletion conditions so that there are depletion regions (455) near each MOS capacitors. When the substrate (453) is illuminated by light (457), electron-hole (e-h) pairs (459) are generated by light bombardment, while some of the electrons will drift to the depletion regions (455) and get trapped near the insulator-semiconductor interface (450). The amount of such trapped charges (450) is proportional to the light intensity shone near the capacitor. When this optical sensor in FIG. 4(e) is connected to pre-charge circuits and sensing circuits similar to those in FIG. 4(a), we can switch one input line at a time using electrical signals similar to those in FIG. 4(d). The amplitude of the resulting coupling voltage Vo detected on the substrate is related to the amount of trapped charges (450) so that it provides a method to measure light intensity at different locations.

While specific embodiments of the invention have been illustrated and described herein, it is realized that other modifications and changes will occur to those skilled in the art. For example, the examples in FIGS. 4(a-e) use MOS capacitors on p-type semiconductor substrate while MOS capacitors on n-type semiconductor substrate also can provide equivalent functions as soon as the polarities of voltages are inverted. We certainly can use a combination of both types of capacitors to support similar operations. In the above examples, the input lines are connected to the conductor lines while the output lines are connected to the semiconductor substrate. We certainly can swap the connection method by using semiconductor substrates as input lines while conductor lines as output lines. The above examples showed simplified cross-section diagrams for IC implementation. The detailed physical structures can be implemented in wide varieties of structures. The 3D device of the present invention can have many layers of coupling devices sharing the same area with prior art devices.

The logic functions of the capacitor coupling circuits shown in FIGS. 4(a-d) are defined by the connections between input signals and MOS capacitors. Once the circuits have been manufactured, their logic functions can not be changed. To provide further flexibility, we can replace the MOS capacitors by floating gate capacitors to support programmable operations.

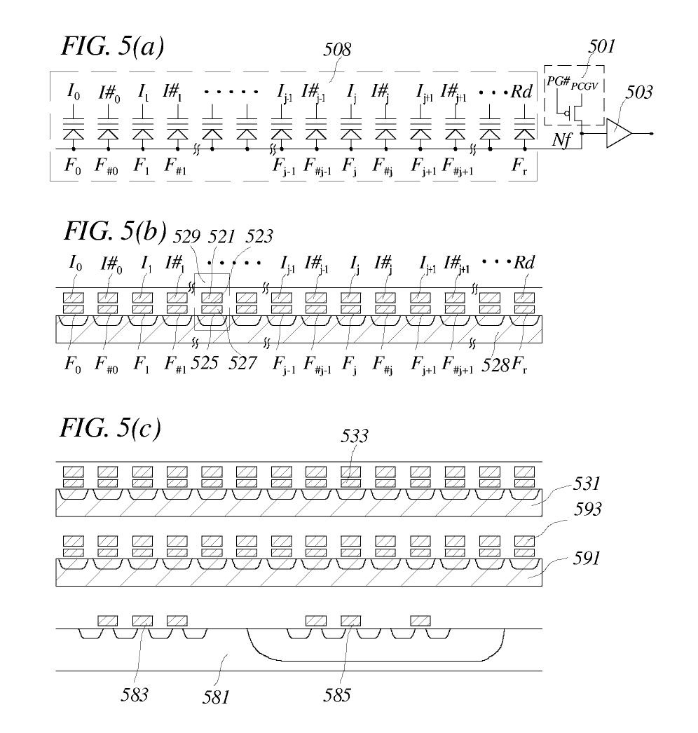

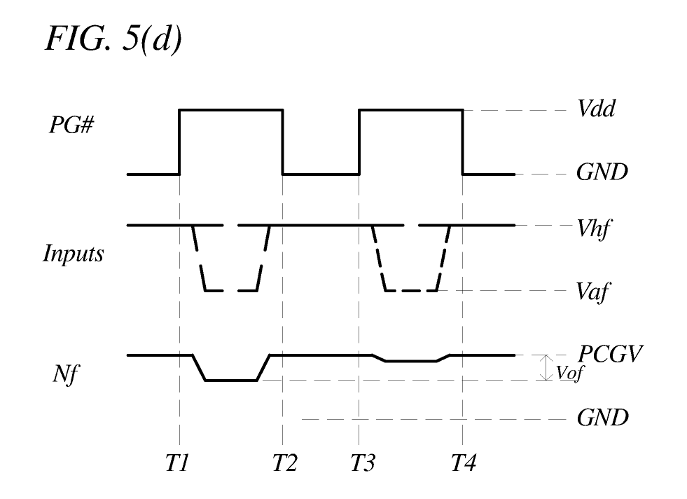

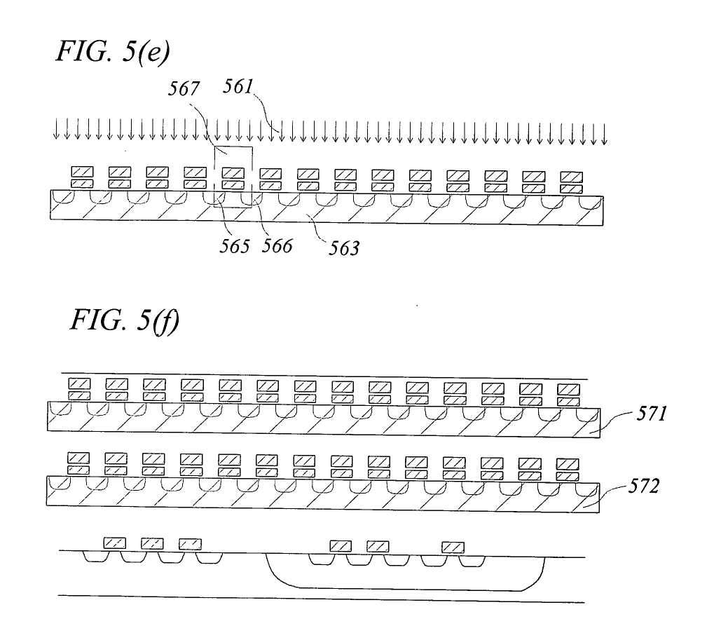

FIG. 5(a) shows the schematic diagram for a programmable coupling circuit of the present invention that can be programmed to support different operations using the same device. As an example, we can use the device in FIG. 5(a) to support the same logic function as the prior art minterm in FIG. 3(a). The PLA input signals (I₀, I₁, . . . Iⱼ₋₁, Iⱼ, Iⱼ₊₁, . . . ) are connected to the negative terminals of floating gate capacitors (F₀, F₁, . . . , Fⱼ₋₁, Fⱼ, Fⱼ₊₁, . . . ), and their complemented input signals (I#₀, I#₁, . . . I#ⱼ₋₁, I#ⱼ, I#ⱼ₊₁, . . . ) are also connected to the negative terminals of other floating gate capacitors (F#₀, F#₁, . . . , F#ⱼ₋₁, F#j, F#ⱼ₊₁, . . . ). The positive terminals of those floating gate capacitors are all connected to an output line (Nf) that is connected to a pre-charge circuit (501) and a sensing circuit (503). Detailed structures for the pre-charge circuit and the sensing circuit are well-known to the art of IC circuit design. The example in FIG. 5(a) uses the same pre-charge circuit (501) as the example (301) in FIG. 3(a). Details of the sensing circuit (503) are not shown because they are well known to the art of IC design.

As discussed previously, storing charge Qf into the floating gate will shift the threshold voltages (Vti, Vta) of a floating gate capacitor by a voltage Vf=Qf/Cg, where Cg is the gate capacitance described in Eq. (8). Therefore, we can “disconnect” a floating gate capacitor (FGC) with p-type substrate by injecting enough electrons into its floating gate causing enough shift in Vta so that it always stays in depletion or inversion condition for all operation voltages. Similarly, we can “connect” an FGC by pulling electrons out of its floating gate so that its Vta falls within operation ranges. According to prior art EPROM terminology, such disconnecting procedure is called “programming” procedure while the connecting procedure is called “erasing” procedure.

Using the floating gate coupling circuit (FGCC) in FIG. 5(a) as an example, we can configure it to support the same function as the capacitor coupling circuit in FIG. 4(a) by the following procedures:

(1)Program the devices (F#₀, F₁, . . . , Fⱼ₋₁, F_{#j-1}, F_{#j}, Fⱼ₊₁, . . . ) with disconnected inputs (I#₀, I₁, . . . , Iⱼ₋₁, I#ⱼ₋₁, I#ⱼ, Iⱼ₊₁, . . . ) in FIG. 4(a). For example, this procedure can be executed by setting those inputs (I#₀, I₁, . . . , Iⱼ₋₁, I#ⱼ, Iⱼ₊₁, . . . ) to a voltage high enough to cause electron tunneling into the floating gates of FGC (F#₀, F₁, . . . , Fⱼ₋₁, F#ⱼ₋₁, F#ⱼ, Fⱼ₊₁, . . . ) to be disconnected, while the remaining inputs are biased to a low voltage so that the remaining FGC are not programmed.

(2)Erase the devices (F₀, F_{#1}, . . . , Fⱼ, F_{#j+1}, . . . ) with connected inputs (I₀, I#₁, . . . , Iⱼ, I#ⱼ₊₁, . . . ) in FIG. 4(a). For example, this procedure can be executed by setting those inputs I₀, I#₁, . . . , Iⱼ, I#ⱼ₊₁, . . . ) to a voltage low enough to remove electrons from floating gates of those FGC (F₀, F_{#1}, . . . , Fⱼ, F_{#j+1}, . . . ) to be connected, while the remaining inputs are biased to a high voltage so that the remaining FGC stay programmed.

After the FGCC in FIG. 5(a) is configured according to the above procedures, the device is ready for functional operation. FIG. 5(d) illustrates the operation waveforms for the FGCC in FIG. 5(a). Before time T1, the circuit is at idle state, and the pre-charge control signal PG# is low so that the output signal Nf is charged to voltage PCGV. At idle state, all the input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) are set at idle state voltage (Vhf) as shown in FIG. 5(d). At this idle state voltage Vhf, all the FGC are biased into depletion conditions or inversion conditions so that their coupling capacitances to Nf are small. To start a logic calculation at time T1, the pre-charge circuit (501) is turned off by pulling PG# high, and the input signals (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) are set to their corresponding logic states. For example, a logic state ‘1’ on input 0 is represented by maintaining I#₀ at Vhf while pulling I₀ down to activation voltage (Vaf); a logic state ‘0’ on input 0 is represented by maintaining I₀ at Vhf while pulling I#₀ down to Vaf. The activation voltage Vaf is a voltage below accumulation threshold voltage (Vta) of erased FGC but higher than Vta of programmed FGC. At time T2, all the inputs return to Vhf while PG# is also pulled low, then the circuit returns to idle state. Another cycle is started at time T3 for another set of input signals, and return to idle state at T4. Under these conditions, if any one of the connected input signals (I₀, . . . Iⱼ₊₁, . . . , I#₁, . . . I#ⱼ, . . . ) is ‘1’, due to capacitor coupling effects, a voltage (Vof) would be coupled to the output line Nc as shown in the first cycle between T1 and T2 in FIG. 4(d). If none of the connected input signals (I₀, . . . Iⱼ₊₁, . . . , I#₁, . . . I#ⱼ, . . . ) is ‘1’, the magnitude of the coupling voltage is much smaller than Vof because all the FGC has low coupling capacitances. The amplitude of the coupling voltage (Vof) can be written as
Vof=(Vta−Vaf)Cif/Cpf (13),

where Cif is the value of capacitance on all the connected inputs that are switched to voltage Vaf, and Cpf is the total capacitance on the output line Nf. The sensing circuit (503) is designed to sense the coupling voltage Vof to provide desired output. Similar to capacitor coupling circuits, we should maximize the (Cif/Cpf) ratio for reliable operations.

For yield improvement purpose, we can add additional connections to the FGCC allowing the possibility to disable the FGCC when it can not function correctly due to manufacture defects. For example, we can add a “valid bit” (Fr) to the FGCC as shown in FIG. 5(a). The input to Fr is connected to a validation signal (Rd) that is always switched to Vaf during logic evaluation, and its output is connected to Nf, as shown in FIG. 5(a). When this valid bit is programmed, it has no effect to the result of FGCC operations. When this valid bit is erased, the output Nf will always be low, which is equivalent to disable the PLA minterm. Adding such valid bit will allow us to invalidate defective minterms in PLA to achieve higher yield. Certainly, we can have more than one such valid bit per minterm, or have one valid bit for an array of FGCC.

FIG. 5(b) is a cross-section diagram showing the physical structures of the FGCC (508) in FIG. 5(a). A floating gate capacitor (529) comprises a conductor gate terminal (521) that is separated from a floating gate (527) by floating gate insulator layer (523). The floating gate (527) is also separated from the semiconductor substrate (528) by gate insulator layer (525). Both the gate terminal (521) and the floating gate (527) are typically made of poly silicon. Each input signal (I₀, I₁, . . . Iⱼ₋₁, Iⱼ, Iⱼ₊₁, . . . , I#₀, I#₁, . . . I#ⱼ₋₁, I#ⱼ, I#ⱼ₊₁, . . . ) is connected to the gate of a floating gate capacitor (F₀, F₁, . . . Fⱼ₋₁, Fⱼ, Fⱼ₊₁, . . . , F#₀, F#₁, . . . F#ⱼ₋₁, F#ⱼ, F#ⱼ₊₁, . . . ). The output note Nf in FIG. 5(a) is an p-type semiconductor substrate (528) in FIG. 5(b). This substrate (528) can be a poly semiconductor layer or a diffusion area in single crystal substrate.

The present invention uses FGC to replace the function of transistors to achieve smaller area and programmable functionalities. The FGCC of the present invention do not need to use single crystal semiconductor as the substrate. It can be manufactured on lower quality semiconductor layers, such as poly silicon layers to achieve higher density. FIG. 5(c) shows the cross-section view for a 3D device of the present invention using poly semiconductor substrates. In this example, there are two layers of poly semiconductor substrates (531, 591). Floating gate capacitors (533, 593) are built on both poly layers (531, 591) to form FGCC of the present invention similar to the structure shown in FIG. 5(b). On the single crystal semiconductor substrate (581) we still can have prior art transistors (583, 585) sharing the same area as coupling circuits of the present invention. Coupling circuits of the present invention also can be placed on the single crystal substrate (not shown in this figure). Such 3D device can achieve device density many times higher than prior art IC.

In many cases, it is desirable to use hot electron effect, instead of tunneling effect, to program floating gate devices. To support hot electron programming, the floating gate device need to be a three-terminal transistor instead of a two-terminal capacitor. FIG. 5(e) illustrates a method to build FGC of the present invention that can support hot carrier programming. The structure of the floating gate devices (567) in FIG. 5(e) is the same as those in FIG. 5(b) except that an ion implant (561) is executed right after the floating gates have been manufactured. The dopants are blocked on areas covered by floating gates, while doping materials can penetrate into the substrate (563) at areas between the floating gates. After thermal treatment, this ion implant (561) procedure creates diffusion areas (565, 566) between the floating gates. In this way, a floating gate (567) and nearby diffusion regions (565, 566) form a transistor. The floating gate devices in FIG. 5(e) forms a series of transistors connected in NAND configuration. Therefore, it can support hot carrier programming and current mode operations in the same ways as prior art NAND flash devices. The hot carrier programming and current sensing methods for the above device operates as serial transistors are the same as prior art NAND flash. Those methods are well-known to those familiar with prior art IC operations so that there is no need to discuss in further details. The floating gate transistors in FIG. 5(e) still can support all the coupling functions of the floating gate capacitors in FIG. 5(b). In other words, the device in FIG. 5(e) can support all operations as conventional NAND flash, while it also can function as the FGCC in FIG. 5(b). Similar to the device in FIG. 5(c), we also can build high density 3D devices. FIG. 5(f) shows a 3D device that has two layers (571, 572) of NAND FGCC.

While specific embodiments of the invention have been illustrated and described herein, it is realized that other modifications and changes will occur to those skilled in the art. The examples in FIGS. 5(a-d) use FGC on p-type semiconductor substrate while FGC on n-type semiconductor substrate also can provide equivalent functions as soon as the polarities of voltages are inverted. We certainly can use a combination of both types of FGC to support similar operations. In the above examples, the input lines are connected to the conductor lines while the output lines are connected to the semiconductor substrate. We certainly can swap the connection method by using semiconductor substrates as input lines while conductor lines as output lines. The above examples showed simplified cross-section diagrams for IC implementation. The detailed physical structures can be implemented in wide varieties of structures. The 3D device of the present invention can have many layers of coupling devices sharing the same area with prior structures. We uses an application on PLA minterm in the above examples, while similar circuits can support other applications such as logic gates, comparators, storage devices, . . . etc.

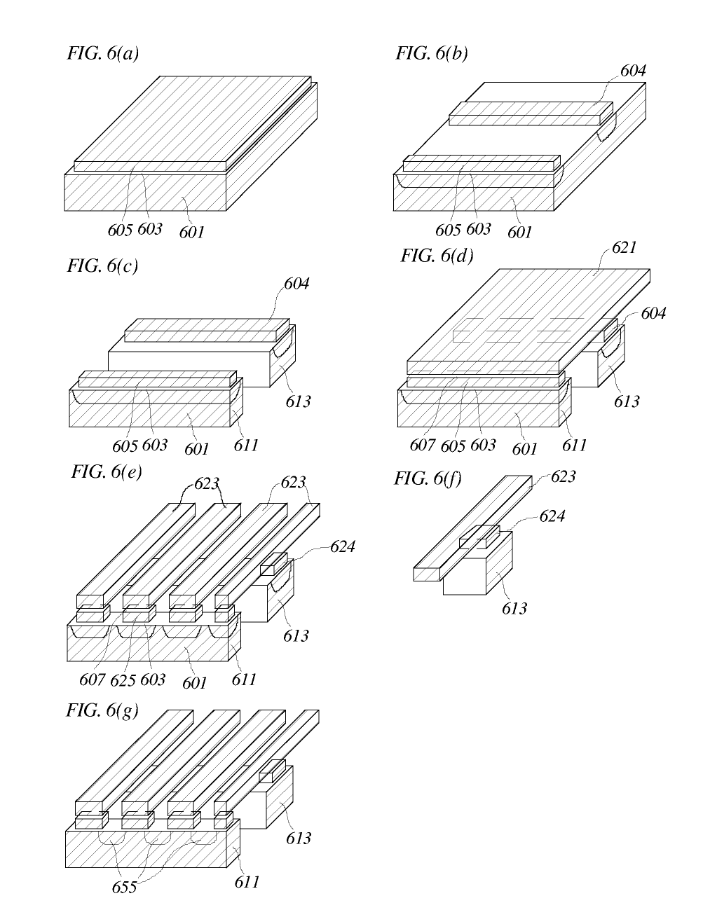

FIGS. 6(a-g) show one example for the IC manufacturing procedures of the present invention in 3D views, including cross-sections views through the middle of FGC devices in both horizontal and vertical directions. FIG. 6(a) illustrates the structure when a floating gate conductor layer (605) is deposited on top of gate insulator thin film (603) that is grown on a semiconductor substrate (601). The floating gate conductor layer (605) is etched into horizontal lines (604) by a masking step, as shown in FIG. 6(b). Another masked etching step defines horizontal substrate lines (611, 61 3) as shown in FIG. 6(c). Isolation insulators are filled into the spaces between output lines (611, 61 3); a floating gate insulator thin film (607) is grown on top of floating gate conductor lines; and then a gate conductor layer (621) is deposited on top of the floating gate insulator layer (607) as shown in FIG. 6(d). The next masking step etches the gate conductor layer (621) into parallel input lines (623), and the floating gate layer is etched into isolated floating gate blocks (624, 625) as shown in FIG. 6(e). The resulting structure has one floating gate capacitor at each intersection between gate conductor lines (623) and substrate output lines (611, 613), forming a two dimensional (2D) array of floating gate capacitors. A horizontal line in FIG. 6(e) contains circuits equivalent to those shown in the cross-section diagram in FIG. 5(b). FIG. 6(f) illustrates the 3D structures for one of the floating gate capacitor in the array. To have hot carrier programming capability, we can use an additional ion implant process on the structure in FIG. 6(e) to form diffusion areas (655) between floating gate devices as shown in FIG. 6(g). In this way, we have a serious of floating gate transistors connected in NAND configuration along each output lines (611, 613). A horizontal line in FIG. 6(g) contains circuits equivalent to those shown in the cross-section diagram in FIG. 5(e).

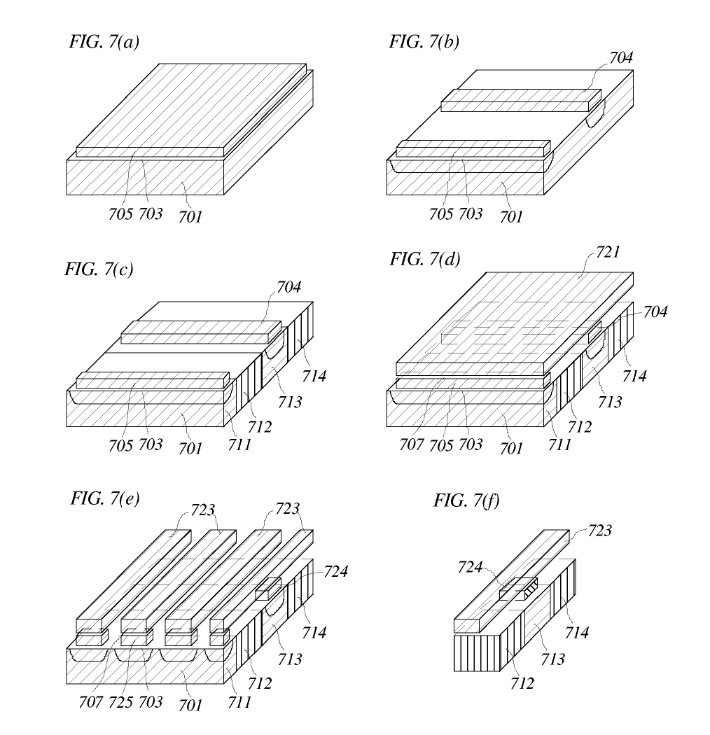

FIGS. 7(a-f) show another example for the IC manufacturing procedures of the present invention in 3D views, including cross-sections views through the middle of FGC devices in both horizontal and vertical directions. FIG. 7(a) illustrates the structure when a floating gate conductor layer (705) is deposited on top of gate insulator thin film (703) that is grown on a semiconductor substrate (701). The floating gate conductor layer (705) is etched into horizontal lines (704) by a masking step, as shown in FIG. 7(b). So far, these manufacture procedures are identical to those in FIGS. 6(a,b). In FIG. 6(c), substrate output lines (611, 613) were separated by etching. FIG. 7(c) shows an alternative method of using n-type diffusion areas (712, 71 4) to separate p-type substrates (701) into p-type output lines (711, 713). These n-type diffusion areas (712, 714) can be manufactured by a masked n-type ion implant procedure. We also can use the same mask to define the horizontal lines (704) as the mask to manufacture the n-type diffusion areas (712, 714). The following steps are similar to those in FIGS. 6(d,e). A floating gate insulator thin film (707) is grown on top of floating gate conductor lines, then a gate conductor layer (721) is deposited on top of the floating gate insulator layer (707) as shown in FIG. 7(d). The next masking step etches the gate conductor layer (721) into parallel input lines (723), and the floating gate layer is etched into isolated floating gate blocks (724, 725) as shown in FIG. 7(e). The resulting structure has one floating gate capacitor at each intersection between gate conductor lines (723) and p-type substrate output lines (711, 713), forming a two dimensional (2D) array of floating gate capacitors. A horizontal line in FIG. 7(e) contains circuits equivalent to those shown in the cross-section diagram in FIG. 5(b). FIG. 7(f) illustrates the 3D structures for one of the floating gate capacitor in the array. The n-type diffusion areas (712, 714) are not only used as separation layers for substrate output lines (711, 713) but also provides as source and drain connections to form transistors with floating gate devices in the array. All the floating gate devices in FIG. 7(e) are connected in wired NOR configuration with nearby n-type diffusion areas (712, 714). Therefore, the structure automatically supports hot carrier programming capability and current mode sensing capability. Higher parasitic capacitance is the major disadvantage of this structure comparing to the structure in FIG. 6(g). Naturally, the polarity of n-type and p-type substrate diffusion areas can be swapped to build similar devices.

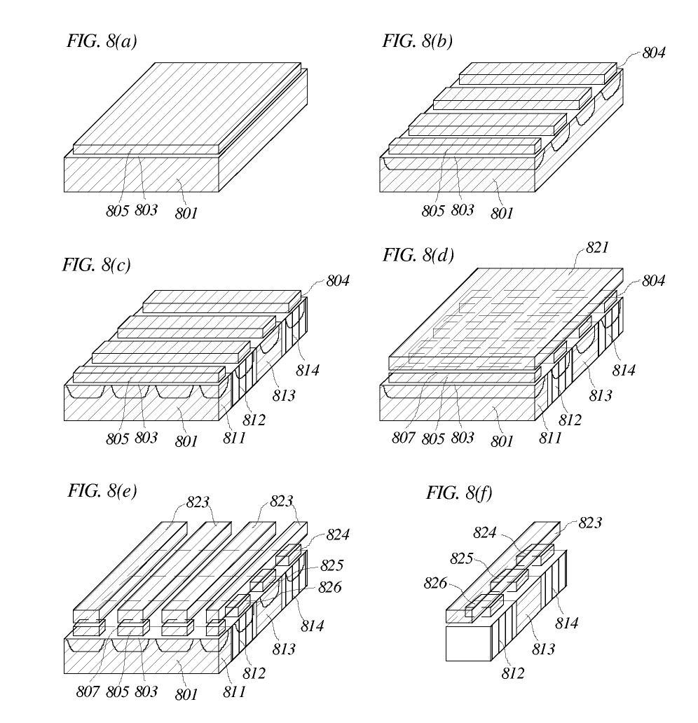

FIGS. 8(a-f) show a method to improve device density for the IC manufacturing procedures of the present invention in 3D views, including cross-sections views through the middle of FGC devices in both horizontal and vertical directions. FIG. 8(a) illustrates the structure when a floating gate conductor layer (805) is deposited on top of gate insulator thin film (803) that is grown on a semiconductor substrate (801). The floating gate conductor layer (805) is etched into horizontal lines (804) by a masking step, as shown in FIG. 8(b). The first step in FIG. 8(a) is identical to that in FIG. 7(a). The second step in FIG. 8(b) is similar to the step in FIG. 7(b) except that the density of floating gate lines (804) is much higher. The next step is to divide the semiconductor substrate (801) into p-type areas (811, 813) and n-type areas (812, 814) as shown in FIG. 8(c). The following steps are similar to those in FIGS. 7(d,e). A floating gate insulator thin film (807) is grown on top of floating gate conductor lines (804), then a gate conductor layer (821) is deposited on top of the floating gate insulator layer (807) as shown in FIG. 8(d). The next masking step etches the gate conductor layer (821) into parallel input lines (823), and the floating gate layer is etched into isolated floating gate blocks (824, 825, 826) as shown in FIG. 8(e). The resulting structure has one floating gate capacitor at each intersection between gate conductor lines (823) and substrate output lines (811, 812, 813, 814), forming a two dimensional (2D) array of floating gate capacitors. The major difference is that we have floating gate devices (825) on p-type substrate lines (811, 813) as well as floating gate devices (824, 826) on n-type substrate lines (812, 814). This structure nearly doubles the device density comparing to the structure in FIG. 7(e). The FGC on p-type substrate operates separated form the FGC on n-type substrate. Both types form transistors connected in wired NOR configuration to support hot carrier programming and current mode sensing operations.

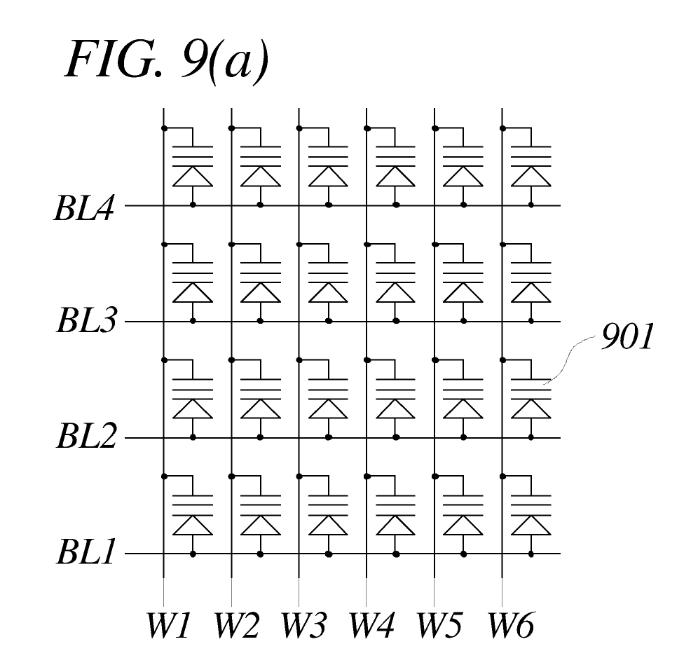

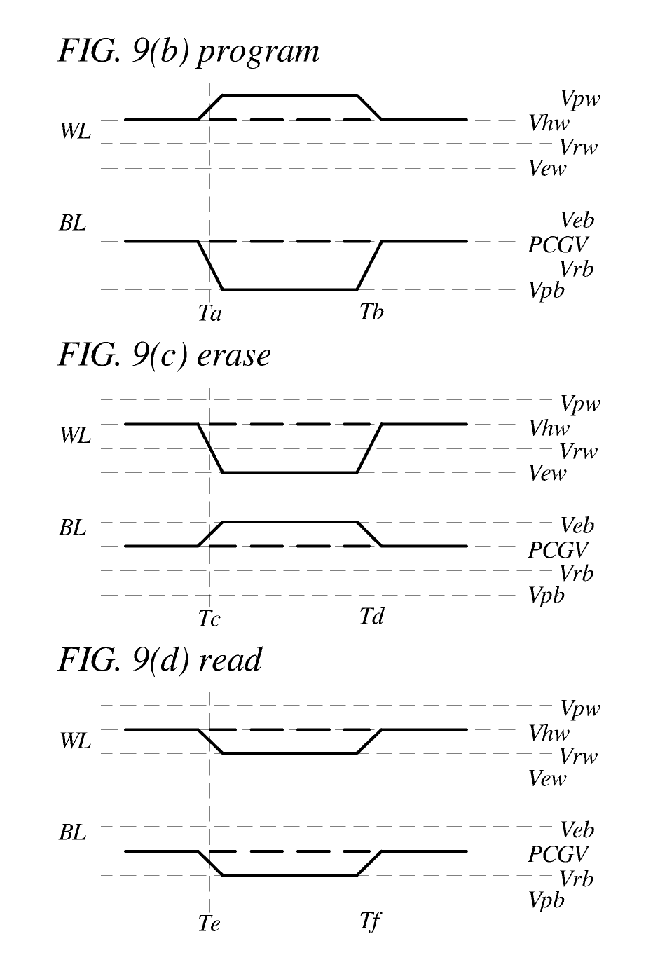

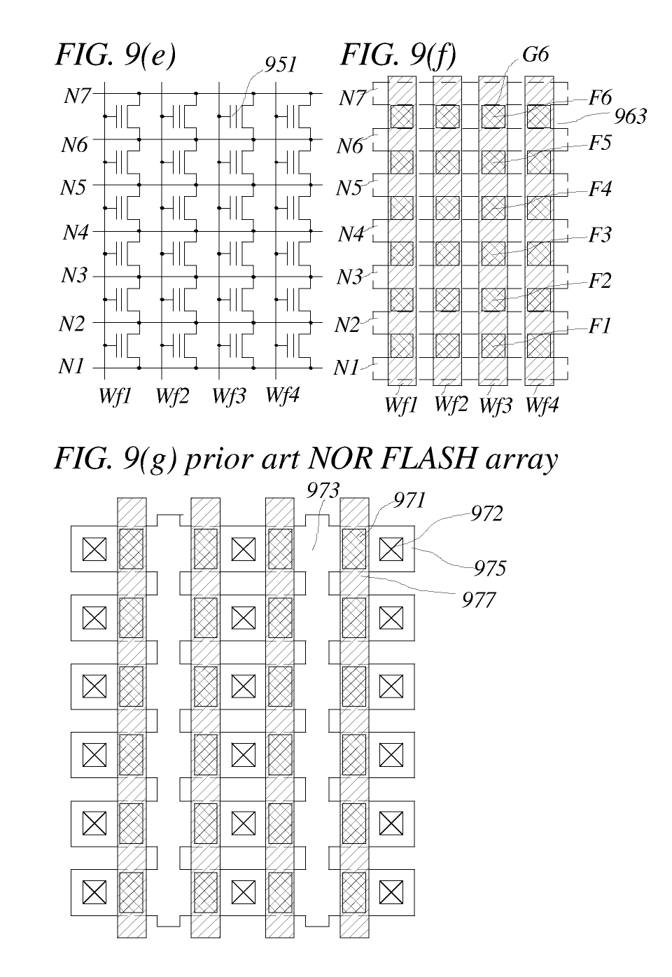

While specific embodiments of the invention have been illustrated and described herein using a PLA interm as example, it is obvious that wide varieties of other applications will occur to those skilled in the art based on similar principles. For example, structures shown in FIGS. (6e, 6g, 7e, 8e) can be configured as logic circuits or as storage devices with equal convenience. FIG. 9(a) shows an example when an array of FGC of the present invention is configured as a data storage device. The gate terminals of FGC (901) are connected to vertical input lines called “word lines” (WL1-WL6). The substrate terminals of those FGC (901) are connected to horizontal lines called “bit lines” (BL1-BL4) using the terminology of prior art memory devices. FIG. 9(a) shows the simplified schematic diagram for a 4 by 6 small array, while the actual storage device can have hundreds of word line and bit lines.

FIG. 9(b) shows the electrical signals for selective programming of the storage device in FIG. 9(a). At idle state, the word lines (WL1-WL6) are all at voltage Vhw, while all bit lines (BL1-BL4) are at pre-charge voltage PCGV. Under idle state condition, all the FGC stays in depletion or inversion conditions to have minimum coupling capacitance between word lines and bit lines. The voltage differences are small enough that the floating gate charge (Qf) in all FGC are not changed. At time Ta, selected word lines are pulled to a high voltage (Vpw) as shown in FIG. 9(b) while all other word lines remain at Vhw. The bit lines (BL1-BL4) are either pulled down to a low voltage (Vpb) or stay at PCGV. At time Tb, all the bit lines and word lines are set back to idle state. An FGC is programmed when its word line is pulled to Vpw, and its bit line is pulled to Vpb. All other FGC remain unchanged. In these ways, we can selectively program any FGC in the array with excellent flexibility. We can selectively program one FGC in the array by pulling its word line to Vpw while setting its bit line to Vpb. We can program the whole array simultaneously by pulling all word lines to Vpw while setting all bit lines to Vpb. We also can selectively program a partial array by setting a plurality of word lines to Vpw while setting a plurality of bit lines to Vpb.

FIG. 9(c) shows the electrical signals for selective erasing of the storage device in FIG. 9(a). The array starts in idle state before time Tc. At time Tc, selected word lines are pulled to a low voltage (Vew) as shown in FIG. 9(c) while all other word lines remain at Vhw. The bit lines (BL1-BL4) are either pulled to a high voltage (Veb) or stay at PCGV. At time Td, all the bit lines and word lines are set back to idle state. An FGC is erased when its word line is pulled to Vew, and its bit line is pulled to Veb. All other FGC remain unchanged. In these ways, we can selectively erase any FGC in the array with excellent flexibility. We can selectively erase one FGC in the array by pulling its word line to Vew while setting its bit line to Veb. We can erase the whole array simultaneously by pulling all word lines to Vew while setting all bit lines to Veb. We also can selectively erase a partial array by setting a plurality of word lines to Vew while setting a plurality of bit lines to Veb.

FIG. 9(d) shows the electrical signals for reading data from the storage device in FIG. 9(a). The array starts in idle state before time Te. At time Te, one of the word lines is pulled to read voltage (Vrw) as shown in FIG. 9(d) while all other word lines remain at Vhw. Vrw is a voltage that is below the accumulation threshold voltage (Vta) of erased FGC while it is higher than Vta of programmed FGC. Therefore, a voltage (Vrb) is coupled to bit lines that are connected to erased FGC, while the bit lines that are connected to programmed FGC see small coupling voltage. The sensing circuits (not shown) connected to each bit line (BL1-BL4) senses the coupling voltages and output the data stored in FGC. In this way, we can read all the data stored in FGC along a selected word line. At time Tf, all the bit lines and word lines are set back to idle state ready for next operation. The above discussion assumed that the FGC in the array have p-type substrate. For the situation when the substrate is n-type, we need to invert polarities of voltages. There are many ways to execute program/erase/read operations of the present invention. For example, hot carrier programming also can be executed. The scope of this invention should not be limited by detailed operation procedures.

The device shown in FIG. 7(e) is a multiple purpose device. If we use the floating gate devices in FIG. 7(e) as programmable coupling capacitors connected between input lines (723) and p-type output lines (711, 713), then it functions as an array of capacitors as shown by the schematic diagram in FIG. 9(a). For exactly the same device, we also can treat it as an array of floating gate transistors connected in wired-NOR configuration as shown by the schematic diagram in FIG. 9(e). The n-type diffusion areas (712, 714) in FIG. 7(e) are used as the sources and drains (N1-N7) of n-channel floating gate transistors (951) in FIG. 9(e). The input lines (723) in FIG. 7(e) are the vertical word lines (Wf1-Wf4) in FIG. 9(e).

To facilitate better understanding, the simplified structural top view of the device in FIG. 9(e) is illustrated in FIG. 9(f). Horizontal n-type diffusion areas (N1-N7) are deposited on p-type substrate (963) to isolate the p-type substrate into horizontal lines. Vertical conductor lines (Wf1-Wf4) forms word lines that connect the gates of floating gate transistors. A floating gate (G6) is placed under each position below word lines (Wf1-Wf4) and between n-type diffusion areas (N1-N7) to form a floating gate transistor (F1-F6). For example, the gate of floating gate transistor F6 is connected to Wf3, its source is N7, its drain is N6, while it has a floating gate (G6) under Wf3 between N7 and N6. Each floating gate transistor in this array shares its source/drain areas with nearby transistors along the vertical direction. For example, F2 shares drain with F1, while F2 shares source with F3. The definition of source versus drain can be swapped because they are symmetric. We will call them source/drain terminals because the meaning of source and drain are exchangeable. All the source/drain areas are connected horizontally in a wired-NOR configuration. All the floating gate devices in the array can be erased simultaneously by pulling all n-type diffusion areas (N1-N7) to a high voltage while keeping all word lines (Wf1-Wf4) at low voltage. Selective erase can happen if we selectively put high voltage on part of the n-type diffusion areas. Since we have transistors instead of capacitors, hot carrier programming is available, but the programming procedure is a little bit more complex than prior art devices because transistors (F1-F6) share source/drain areas with nearby transistors on the same word line (Wf3). For example, if we want to program transistor F6, we put high voltage on its word line (Wf3), pull N7 to ground, and N6 to a drain voltage proper for hot carrier programming (Vdp). In this way, F6 will be programmed by hot carrier effect. The problem is that transistor F5 is connected to the same word line (Wf3) and shares the same drain (N6) with F6; we need to avoid accidental programming of F5. This problem can be avoided by floating N5 or by putting Vdp on N5 when we are programming F6. In this way, only half of the transistors along a word line can be programmed simultaneously. Programming the other half requires a separated operation. The device in FIG. 9(e) also allows current mode read operations with similar problem. For example, if we want to read transistor F6, we activate its word line (Wf3), pull N7 to ground, and N6 will be pull down by transistor current if F6 is erased, while there is no current if F6 is programmed, allowing a sensor connected to N6 to detect the status of F6. The problem is that transistor F5 is connected to the same word line (Wf3) and shares the same drain (N6) with F6; F5 also can provide current to N6 if it is erased. We can avoid the influence of F5 by floating N5 or by putting a pre-charge voltage on N5. In this way, we can only read half of the transistors along a word line simultaneously. Reading the other half requires a separated operation.

The device in FIG. 9(e) provides all functions equivalent to prior art NOR FLASH devices. FIG. 9(g) shows structural top view for an array of prior art NOR FLASH memory cells. Floating gate transistors (971) are formed under vertical word lines (977), and between source (973) and drain (975) diffusion areas. These floating gate transistors (971) share source and drain with nearby transistors along horizontal direction. The sources (973) are connected together through diffusion connections, while the drains are connected to horizontal metal bit lines (not shown) through metal contacts (972). Comparing the floating gate transistor array of the present invention in FIG. 9(f) with the equivalent prior art array in FIG. 9(g), the difference is that we rotated the orientation of transistors by 90 degrees relative to the word line direction. This 90 degree rotation allow us to make wired-NOR connections with diffusion areas, while the same diffusion areas also serve the purpose for isolation. There is no need to have any metal contact (973) in the array. The result is dramatic reduction in area. Typically this 90 degree rotation can improve device density by 3 to 5 times. The price to pay is the complexity in read and program operations as discussed in the above sections. We can further double the device density using the device structure shown in FIG. 8(e), which is equivalent to have an array of n-channel floating gate transistors overlap with an array of p-channel floating gate transistors, both in the configuration shown in FIG. 9(e).

FIGS. 9(a-f) demonstrate that FGC array of the present invention can support all the functions of electrically erasable/programmable read only memory (EEPROM) as well as all the functions of FLASH memory. With the flexibility to build 3D devices, storage devices of the present invention can achieve storage density higher than all prior art storage devices.

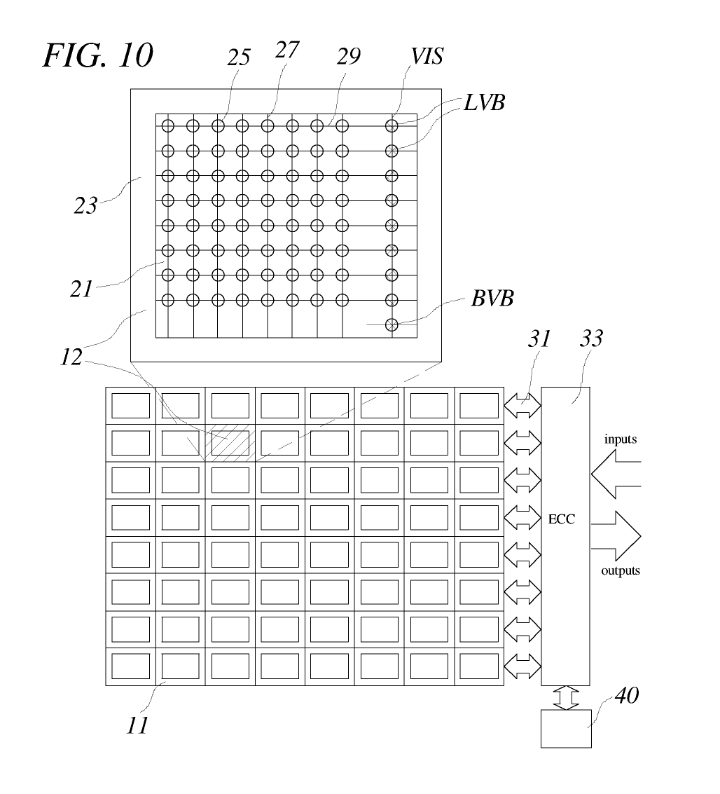

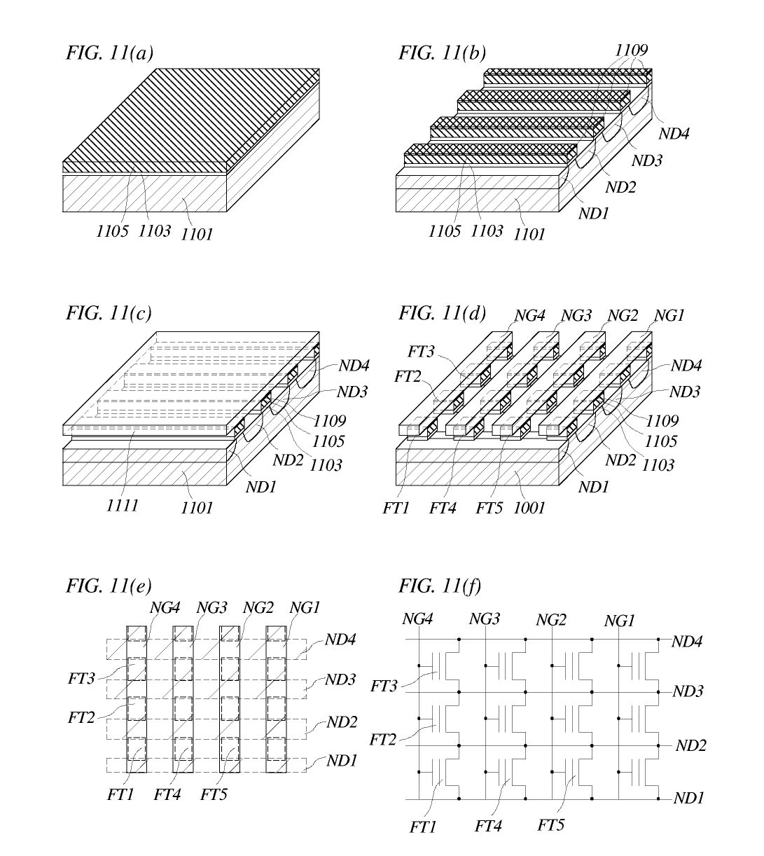

The major problem for 3D circuits of the present invention is in yield. Although voltage coupling circuits are less sensitive to manufacture defects than current mode circuits, we still can not expect FGC built on low quality substrates to have the same yield as those build on single crystal substrates. It is therefore necessary to provide yield enhancement methods for 3d devices of the present invention. FIG. 10 shows a simplified block diagram illustrating various yield enhancement methods. In this example, a device of the present invention comprises an array of smaller blocks (11). Each block (11) comprises an FGC array (21) and peripheral circuits (23) as shown by the magnified picture (12) on top of FIG. 10. Block peripheral circuits (23) comprises pre-charge circuits, sensing circuits, decoders, controller, . . . etc that are not shown in FIG. 10 for simplicity. The FGC array (21) comprises an array of FGC (25) connected between vertical input lines (27) and horizontal output lines (29). When this device is a storage device, the input lines (27) would be word lines while the output lines (29) would be bit lines, but this structure is also applicable to other types of devices such as PLA. One yield enhancement method is to add one or more FGC for each input line (27) as “line valid bit” (LVB). These LVB's are controlled by additional validation input signals (VIS). Normally, LVB and VIS have no effects on the function of the device. When the circuits related to one of the output lines (29) are found to fail, the LVB on the failed line is set to disable that line, and the function of the failed line is replaced by another functional line. We also can equip each block (11) with one or more “block valid bits” (BVB). BVB normally have no effects on the function of the device. When a block (11) is found to fail, and the failures can not be fixed by other methods, the BVB on the failed block are set to disable that block, and the function of the failed block is replaced by another block. At upper level, we can have error correction code (ECC) circuits (33) to execute error detection/correction for the input/outputs (31) of the device. ECC mechanisms are well known to the art so that there is no need to discuss in details. We also can use a redundant device (40) that replaces the functions of failed FGC arrays for a programmed set of conditions. Details of the redundant device operations are also well known to the art. Using one or more yield enhancement methods described above, 3D devices of the present invention can achieve excellent yield.

FIGS. 11(a-d) are three dimensional symbolic diagrams showing an example of the manufacture procedures for the floating gate transistor array shown in FIGS. 9(e,f). FIG. 11(a) illustrates the structures when a floating gate conductor layer (1105) is deposited on top of gate insulator thin film (1103) that is grown on a semiconductor substrate (1101). The dimensions in our figures are often not drawn to scale. A floating gate insulator thin film (1109) is grown on top of the floating gate conductor layer (1105), and the floating gate conductor layer (1105) is etched into horizontal lines by a masking step as shown in FIG. 11(b). Typically, this floating gate insulator layer (1109) is made of oxide-nitride-oxide (ONO) composite insulator layers. Diffusion areas (ND1-ND4) are formed between the floating gate conductor lines (1105) by self-aligned ion implantation as shown in FIG. 11(b). These diffusion areas (ND1-ND4) should be n-type diffusion areas if the substrate (1101) is p-type. These diffusion areas (ND1-ND4) also can be p-type diffusion areas if the substrate (1101) is n-type. At this stage the space between the horizontal floating gate conductor lines are filled with insulators (not shown). These diffusion areas (ND1-ND4) form source/drain terminals for floating gate transistors and provide bit line connections for the array. These diffusion areas (ND1-ND4) also can be connected to power or ground to support different operations. The above manufacture procedures are well known to integrated circuit industry; there is no need to provide further details. FIG. 111(c) illustrates the next step when a gate conductor layer (1111) is deposited on top of the floating gate insulator layer (1109). The next masking step etches the gate conductor layer (1111) into vertical word lines (NG1-NG4), and the floating gate structures are etched into isolated floating gate blocks as shown in FIG. 11(d). The resulting structures in FIG. 11(d) have one floating gate transistor (FT1-FT5) at each intersection between word lines (NG1-NG4) and the active areas between bit lines (ND1-ND4), forming a two dimensional array of floating gate transistors as illustrated by the top view shown in FIG. 11(e). FIG. 11(f) is a schematic circuit diagram showing the connections for the floating gate transistor array in FIGS. 11(d,e).

All the manufacture procedures used in the above example are well known to The IC industry. The above floating gate array is different from prior art floating gate array shown in FIG. 9(g) by the connections between the floating gate transistors in the array. For a prior art array, each transistor connected to the same word line is connected to different bit lines. For a floating gate array of the present invention, the floating gate transistors that share the same word line can share the same bit line with nearby floating gate transistors. For example, the transistor FT2 in FIGS. 11(d-f) shares the same word line (NG4) with the transistor FT1, while their source/drain terminals are connected together to the same bit line (ND2). For another example, the transistor FT2 in FIGS. 11(d-f) shares the same word line (NG4) with the transistor FT3, while their source/drain terminals are connected together to the same bit line (ND3). This structure allows us to use diffusion areas for bit line connection without using metal contacts; the resulting devices are therefore smaller than that of prior art devices. For prior art arrays arranged in NOR configuration, nearby transistors are electrically separated by field isolation insulators. For a floating gate array of the present invention, nearby floating gate transistors are naturally separated without the need to have field isolation layer in the array. For this example, the transistor FT4 in FIGS. 11(d,e) is electrically separated from nearby transistor FT1 because the active area between them is of the opposite carrier type of the transistor channel carriers. There is no need to put field isolation insulator between them. For another example, the transistor FT4 is electrically separated from nearby transistor FT5 for the same reasons. Such natural isolation also helps to reduce the areas for floating gate transistor arrays of the present invention.

The price to pay for such reduction in area is increased complexity in control. For example, if we want to read the status of FT2 by tuning on its word line (NG4), pulling down its source (ND3), and detecting the current or voltage on its bit line (ND2), we need to avoid the interference from the transistor FT1 because FT1 is also connected to the same bit line (ND2) and it is turned on by the same word line (NG4). As discussed previously, this problem can be solved by proper bias on ND1. For n-channel transistors, we can bias ND1 to high voltage, and pre-charge ND2 to high voltage. Under this condition, the driving current of FT1 is small due to body effects; we can detect the status of FT2 by measuring the voltage or current on ND2 with minimal interferences from FT1. For p-channel transistor, the polarity of voltages is inverted. In such ways, we can read half of the data from floating gate transistors connected to the same word line. There are many other ways to overcome this limitation, but we will not discuss those methods in this patent application.

While specific embodiments of the invention have been illustrated and described herein, it is realized that other modifications and changes will occur to those skilled in the art. For the above examples, word lines are all traveling in the same directions (called word line direction) while in many implementations word lines can travel to different directions locally. The term “word line direction” means overall direction from array point of view instead of local direction. It is also possible to have more than one word line direction in an array. Similarly, for the above examples, bit lines are all traveling in the same directions while in many implementations bit lines can travel to different directions locally. The term “bit line direction” means overall direction from array point of view instead of local direction. It is also possible to have more than one bit line direction in an array. In the above example, we call source/drain connection lines as bit lines. Sometimes, parts of such lines are dedicated to power line connections. We did not distinguish bit lines from power lines in our examples because the same lines can be used for both functions in our examples. However, we should define bit lines as the source/drain connections used to read/write data from and into the non-volatile memory transistors. Prior art non-volatile memory transistors on the same word line can share the same power lines but they can not share the same bit lines.

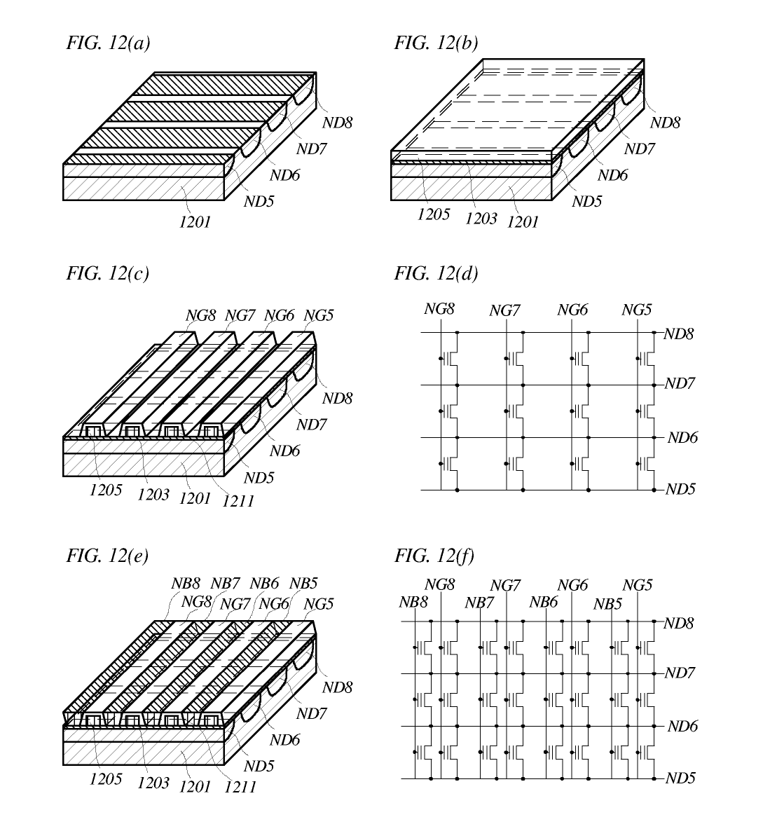

There are many possible manufacture procedures available to build floating gate transistor arrays of the present invention. The above structure is also applicable to there type of non-volatile memory devices. FIGS. 12(a-f) show additional examples of the present invention.

FIG. 12(a) illustrates the structures when diffusion areas (ND5-ND8) are formed on a substrate (1201). These diffusion areas (ND5-ND8) should be n-type diffusion areas if the substrate (1201) is p-type. These diffusion areas (ND5-ND8) also can be p-type diffusion areas if the substrate (1201) is n-type. These diffusion areas (ND5-ND8) form source/drain terminals for non-volatile memory transistors and provide bit line connections for the array.

In the following steps, a floating gate conductor layer (1205) is deposited on top of a charge trapping gate insulator thin film (1203) that is grown on the semiconductor substrate (1201) as shown in FIG. 12(b). Typically, this charge trapping gate insulator thin film (1203) is made of oxide-nitride-oxide (ONO) or other types of composite insulator thin films. As well known to the art, such charge trapping gate insulator thin film (1203) can trap charges injected into it causing changes in transistor threshold voltage in similar ways as a floating gate transistor. While floating gate is typically made of conductor thin film such as poly silicon. The charge trapping gate insulator thin film (1203) is an insulator so that the trapped charge won't move around within it. In our definition, a transistor with such charge trapping gate insulator thin film (1203) as part of its gate structure is also a floating gate transistor because its current-voltage relationship also can be changed by injecting charges into its gate structure. In this patent application, we define a “non-volatile memory transistor” as a transistor that can adjust its current-voltage relations by trapping electrical charges in its gate structures. Examples for the “non-volatile memory transistor” are floating gate transistors and transistors with charge trapping gate insulators.

The next masking step etches the gate conductor layer (1205) into vertical word lines (NG5-NG8) as shown in FIG. 12(c). In this example, the charge trapping gate insulator thin film (1203) between the word lines is not etched away because it is an insulator thin film. For other implementations it maybe removed in the areas between the word lines. In this example, the word lines (NG5-NG8) are also coated with protection insulators (1211) as a common practice in IC industry. The resulting structures in FIG. 12(c) have one non-volatile memory transistor at each intersection between word lines (NG5-NG8) and the active areas between bit lines (ND5-ND8), forming a two dimensional array of non-volatile memory transistor as illustrated by the schematic circuit diagram in FIG. 12(d). We can further improve the density of the non-volatile memory array by filling the spaces between the word lines (NG5-NG8) with another layer of gate conductor lines (NB5-NB8) as shown in FIG. 12(e). The structures shown in FIG. 12(e) can be achieved by well known IC manufacture procedures. For example, we can deposit poly silicon thin film as the second gate conductor layer, and use well known etch back or polishing procedures to fill the additional word lines (NB5-NB8) into the space between the original word lines (NG5-NG8). Such manufacture procedures are self-aligned because the protection insulator (1211) of the first set of word lines (NG5-NG8) provides the structures needed to define the locations and dimensions of the second set of word lines (NB5-NB8). The resulting structures in FIG. 12(e) have one additional non-volatile memory transistor at each intersection between added word lines (NB5-NB8) and the active areas between bit lines (ND5-ND8), forming a two dimensional array of non-volatile memory transistor as illustrated by the schematic circuit diagram in FIG. 12(f). The density of the non-volatile memory array is therefore doubled. For the example shown in FIGS. 12(e,f), the electrical separation between nearby transistors are separated naturally by other transistors.

The examples shown in FIGS. 12(a-f) demonstrated that the array structures of the present invention are applicable to floating gate transistors as well as non-volatile transistors with charge trapping gate structures. Significant area saving and simplifications in manufacture procedures are achievable by the present invention.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. An electrical device comprises: (a)an array of non-volatile memory transistors, (b)a plurality of word lines that connect the gate terminals of a plurality of non-volatile memory transistors along a word line direction, and (c)a plurality of bit lines that connect the source/drain terminals of a plurality of non-volatile memory transistors along a bit line direction different from said word line direction, wherein pairs of said non-volatile memory transistors that share the same word line also share the same bit line with nearby non-volatile memory transistors.

2. The non-volatile memory transistors in claim 1 are electrically separated from nearby non-volatile memory transistors along bit line direction by active areas.

3. The non-volatile memory transistors in claim 1 are electrically separated from nearby non-volatile memory transistors along bit line direction by transistors.

4. The non-volatile memory transistors in claim 1 are floating gate transistors.

5. The non-volatile memory transistors in claim 1 are transistors with charge trapping gate structures.

6. A method for arranging an array of non-volatile memory transistors comprising the steps of: (a)providing a plurality of word lines for connecting the gate terminals of a plurality of non-volatile memory transistors along word line direction, (b)providing a plurality of bit lines for connecting the source/drain terminals of a plurality of non-volatile memory transistors along a bit line direction different from said word line direction, and (c)arranging pairs of nearby non-volatile memory transistors to share the same bit line with nearby non-volatile memory transistors that share the same word line.

7. The method of arranging an array of non-volatile memory transistors in claim 6 comprising a step of using active areas to provide electrical separation to nearby non-volatile memory transistors along bit line direction.

8. The method of arranging an array of non-volatile memory transistors in claim 6 comprising a step of using transistors to provide electrical separation to nearby non-volatile memory transistors along bit line direction.

9. The non-volatile memory transistors in claim 6 are floating gate transistors.

10. The non-volatile memory transistors in claim 6 are transistors with charge trapping gate structures.
